(19) United States
(12) Patent Application Publication
(10) Pub. No.: US 2014/0360554 A1
(43) Pub. Date: Dec. 11, 2014

(54) METHOD OF PRODUCING TWO OR MORE THIN-FILM-BASED INTERCONNECTED PHOTOVOLTAIC CELLS

(71) Applicant: Dow Global Technologies LLC, Midland, MI (US)

(72) Inventors: Rebekah K. Feist, Midland, MI (US); Michael E. Mills, Midland, MI (US)

(21) Appl. No.: 14/366,160

(22) PCT Filed: Dec. 11, 2012
(86) PCT No.: PCT/US2012/068887

§ 371 Date: Jun. 17, 2014

Related U.S. Application Data
(60) Provisional application No. 61/583,238, filed on Jan. 5, 2012.

(51) Int. Cl. H01L 25/04

(52) U.S. Cl. CPC H01L 25/045
USPC 136/245; 438/67; 136/244

(57) ABSTRACT

The present invention is premised upon a method of producing two or more thin-film-based interconnected photovoltaic cells comprising the steps of: a) providing a photovoltaic article comprising: a flexible conductive substrate, at least on photo-electrically active layer, a top transparent conducting layer, and a carrier structure disposed above the tap transparent layer; b) forming one or more first channels through the layers of the photovoltaic article; c) applying an insulating layer to the conductive substrate and spanning the one or more first channel; d) removing the carrier structure; e) forming an addition to the one or more first channels through the insulating layer; f) forming one or more second channels off set from the one or mom first channels through the insulating layer to expose a conductive surface of the flexible conductive substrate; g) applying a first electrically conductive material to the conductive surface of the flexible conductive substrate via the one or more; second channels; h) applying an electrically conductive film to the first insulating layer, wherein the film is hi electrical communication with the flexible conductive substrate via the first electrically conductive material; J) applying a second electrically conductive material above the top transparent conducting layer and through the one or more first channels, electrically connecting the layers of the photovoltaic article from step b to the electrically conductive

### FIELD OF THE INVENTION

The present invention relates to an improved method of producing two or more thin-film-based interconnected photovoltaic cells, more particularly to an improved method of producing two or more thin-film-based interconnected photovoltaic cells from a photovoltaic article that includes a flexible conductive substrate, at least one photoelectrically active layer, and a top transparent conducting layer.

### BACKGROUND

Efforts to improve the manufacture of photovoltaic devices, particularly thin-film-based interconnected photovoltaic cells have been the subject of much research and development of the recent past. Of particular interest is the ability to manufacture thin-film-based interconnected photovoltaic cells in a variety of shapes and sizes, while maintaining efficient production and a relatively low capital investment, thus making the finished product more affordable. It has been a goal of the industry to develop these process and techniques that can help make the finished product more affordable while still producing quality products.

In one application, these thin-film-based interconnected photovoltaic cells are used as the electricity generating component of larger photovoltaic devices. The available shapes and sizes of relatively low cost thin-based-film interconnected photovoltaic cells may limit the design of the larger photovoltaic devices and systems of devices, and thus the possible market for them. To make this full package desirable to the consumer, and to gain wide acceptance in the marketplace, the system should be inexpensive to build and install. The present invention ultimately may help facilitate lower generated cost of energy, making PV technology more competitive relative to other means of generating electricity.

It is believed that the existing art for the manufacture of thin-film-based interconnected photovoltaic cells have relied upon methods and techniques that utilize interconnected steps prior to the completing of the photovoltaic article, for example wherein at least one scribe or cut is made during the article fabrication process.

Among the literature that can pertain to this technology include the following literature and U.S. patent documents: F. Kessler et al, “Flexible and monolithically integrated CIGS-modules”, MRS 668: H3.61-H3.6.6 (2001); U.S. Pat. Nos. 4,754,544; 4,697,041; 5,131,954-5,639,314; 8,372,538; 7,122,398; and 2010/1236496, all incorporated herein by reference for all purposes.

### SUMMARY OF THE INVENTION

The present invention is directed to a PV device that addresses at least one or more of the issues described in the above paragraphs.

Accordingly, pursuant to one aspect of the present invention, there is contemplated a method of pressing two or more thin-film-based interconnected photovoltaic cells comprising the steps of: a) providing a photovoltaic article, comprising: a flexible conductive substrate, at least one pholoelectrically active layer, a top transparent conducting layer, and a carrier structure disposed above the top transparent layer; b) forming one or more first channels through the layers of the photovoltaic article; c) applying an insulating layer to the conductive substrate and spanning the one or more first channel; d) removing the carrier structure; e) forming an addition to the one or more first channels through the insulating layer; f) forming one or more second channel off set from the one or more first channels through the insulating layer to expose a conductive surface of the flexible conductive substrate; g) applying a first electrically conductive material to the conductive surface of the flexible conductive substrate via the one or more second channels; h) applying an electrically conducive film to the insulating layer, wherein the film is in electrical communication with the flexible conductive substrate via the first electrically conductive material; i) applying a second electrically conducive material above the top transparent conducting layer and through the one or more first channels, electrically connecting the layers of the photovoltaic article from step b to the electrically conductive film; j) forming one or more first isolation channels through the electrically conductive film; k) applying a second insulating layer below the electrically conductive film; l) forming one or more second isolation channels through the layers of the photovoltaic article, thus producing two or more interconnected photovoltaic cells.

The invention may be further characterized by one or any combination of the features described herein, such as comprising the steps of at least partially filling the one or more second isolation channels with an electrically insulating material; the electrically insulating material comprises silicon oxide, silicon nitride, titanium oxide, aluminum oxide, non-conductive epoxy, silicone, polyester, polyfluorene, polyolefin, polyimide, polyamide, polyethylene or combinations of the like; the insulating layer comprises polyester, polyolefin, polyimide, polyamide, polyethylene; the forming step is carried out by scribing, cutting, ablating, or combinations of the like, the photovoltaic article cell is in roll form; the second insulating layer functions as a bottom carrier film; the width of the channels of the forming step are between 1-5000 micron; a photovoltaic article is formed by the above method.

It should be appreciated that the above referenced aspects and examples are non-limiting, as others exist within the present invention, as shown and described herein.

### DESCRIPTION OF THE DRAWINGS

FIG. 1A shows the layers of a photovoltaic article.

FIG. 1B shows the layers of a photovoltaic article with a first channel.

FIG. 1C shows the layers of a photovoltaic article with a first channel in a different location and an insulating layer.

FIG. 1D shows the layers of a photovoltaic article with first channel, an addition to the first channel, a second channel and an insulating layer.

FIG. 1E shows the layers of a photovoltaic article with a first channel, an addition to the first channel, a second channel having electrically conductive material therein, and an insulating layer.

FIG. 1F shows the layers of a photovoltaic article with a first channel, an addition to the first channel, a second channel having electrically conductive material therein, a third channel in an electrically conductive film and an insulating layer.

FIG. 1G shows the layers of a photovoltaic article with a first channel, an addition to the first channel, a second channel having electrically conductive material therein, a third channel in an electrically conductive film and two insulating layers.

FIG. 1H shows a photovoltaic device having a fourth channel.

FIG. 1I shows a photovoltaic device with multiple channels.

### DETAILED DESCRIPTION OF THE PREFERRED EMBODIMENT

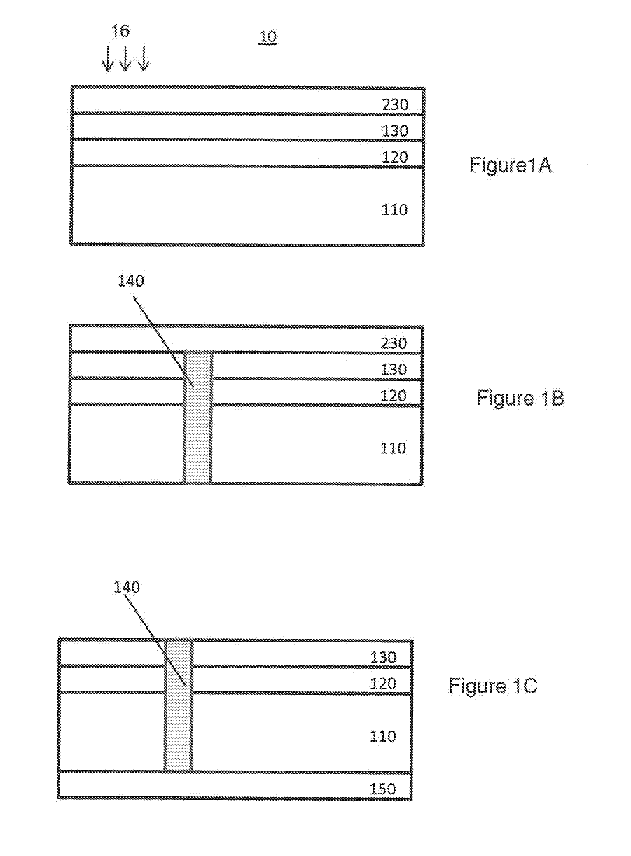

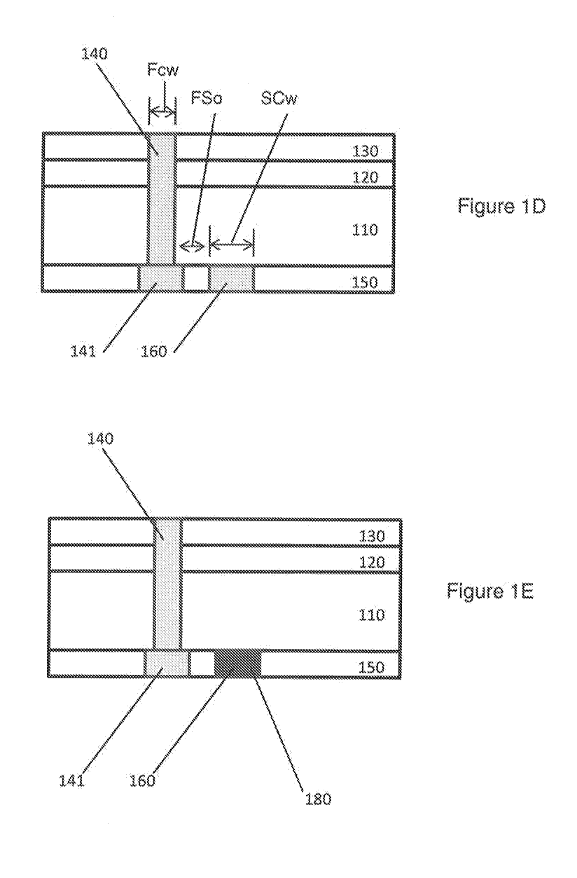

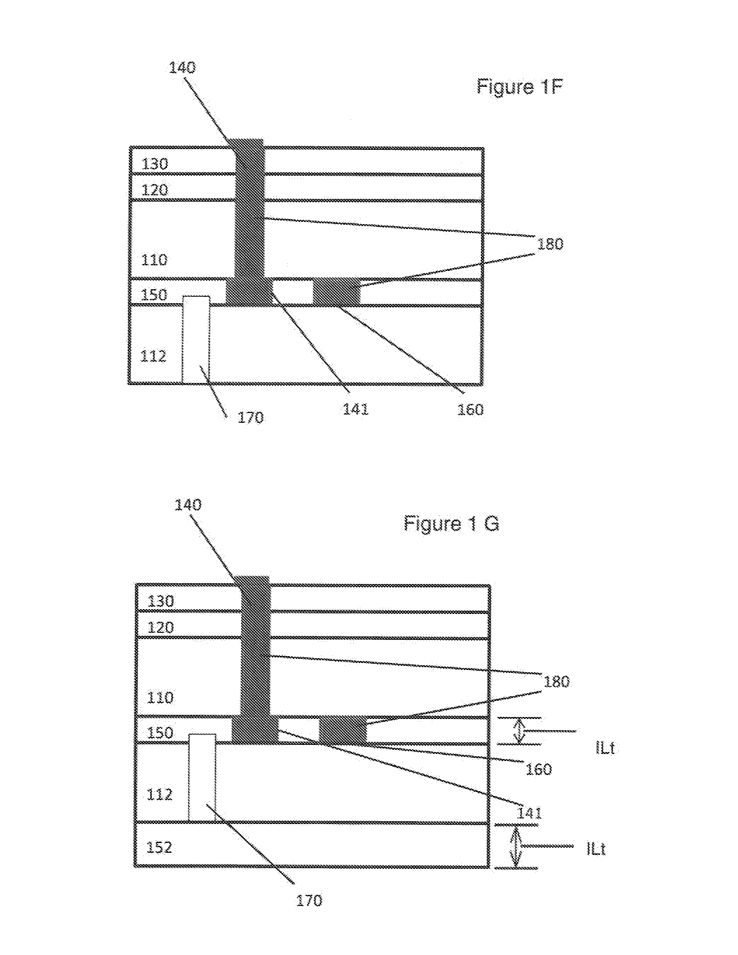

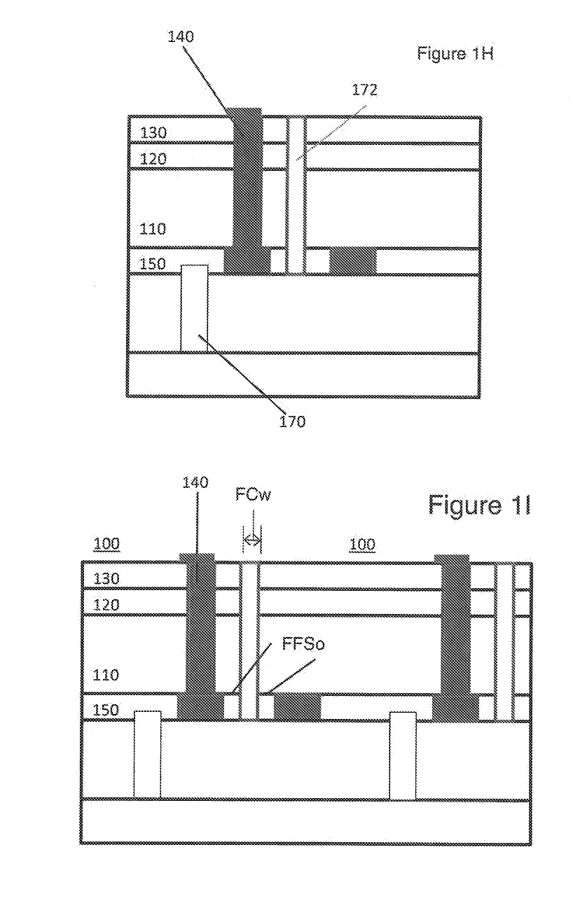

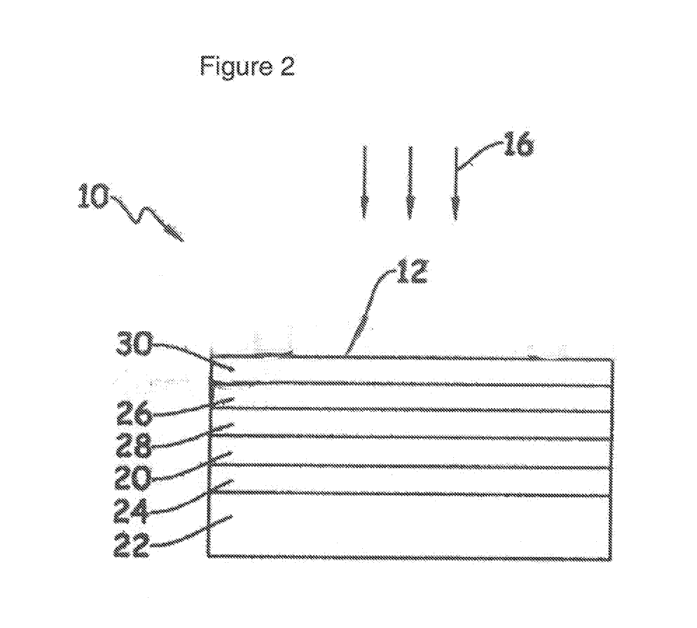

The present invention related to an improved method of producing two or more thin-film-based interconnected photovoltaic cells (For example as shown in FIG. 1I) from a photovoltaic article 10 that includes a flexible conductive substrate, at least one photoelectrically active layer, and a top transparent conducting layer. It is contemplated that the present invention produces a unique manufacturing solution that allows for the creation and interconnection of photovoltaic cells (e.g. two or more) from a photovoltaic article that is essentially already fabricated. The present invention may allow for thin-film-based interconnected photovoltaic cells with unique shapes and sizes to be manufactured with relatively low capital investment and without dedicated equipment or processes within the photovoltaic article manufacturing lines. Taught within this disclosure is the inventive method, as well as an explanation of the structure some of the typical photovoltaic articles that may be used as the inputs to the inventive process. The disclosed photovoltaic article discussed herein should not be considered limiting on the inventive method and other possible base photovoltaic article are contemplated.

### Method

It is contemplated that the inventive method functions to take a base photovoltaic article 10 and transform it into interconnected photovoltaic cells 100, independent of the manufacturing of the base article. FIG. 1A is a representative example of the article 10 and method of this invention. The inventive method includes at least the steps of: a) providing a photovoltaic article comprising: a flexible conductive substrate, at least one photoelectrically active layer, a top transparent conducting layer, and a carrier structure disposed above the top transparent layer; b) forming one more first channels through the layers of the photovoltaic article; c) applying an insulating layer to the conductive substrate and spanning the one or more first channel; d) removing the carrier structure; e) forming an addition to the one or more first channels through the insulating layer f) forming one or more second channels off set from the one or more first channels through the insulating layer to expose a conductive surface of the flexible conductive substrate; g) applying a first electrically conductive material to the conductive surface of the flexible conductive substrate via the one or more second channels; h) applying an electrically conductive film to the insulating layer, wherein the film is in electrical communication with the flexible conductive substrate via the first electrically conductive material; i) applying a second electrically conductive material above the top transparent conducting layer and through the one or more first channels, electrically connecting the layers of the photovoltaic article from step b to the electrically conductive film; j) forming one or more third channels through the electrically conductive film; k) applying a second insulating layer below the electrically conductive film: l) forming one or more fourth channel through the layers of the photovoltaic article, thus producing two or more interconnected photovoltaic cells. Optional stops may include one or more of the following; packaging with protective layers; forming interconnects to external electric devices; packaging in module format (e.g. shingle); or using a part of a photovoltaic cell as described in U.S. Publication 2011/0100436.

It is contemplated that a photovoltaic article 10 is provided in the beginning of the inventive method/process. The article 10 is the basis for the creation of multiple interconnected photovoltaic cells 100 through this inventive method/process. The article should be comprised of at least three layers (list from bottom to top of the article): a flexible conductive substrate 110, at least one photoelectrically active layer 120, and a top transparent conducting layer 130. It is also contemplated (and preferred) that the article 10 include a carrier structure 230 disposed above the top transparent layer. The carrier structure being removable, at least removable in such a way as not to damage the rest of the article in the removal process. It is contemplated that the substrate or layers disclosed within this application may comprise a single layer, but any of these independently can be formed from multiple sublayers as desired. Additional layers conventionally used in photovoltaic articles as presently known or hereafter developed may also be provided. If is contemplated that presently known photovoltaic articles for use in the present invention may include: group IB-IIIB chalcogenide type cells (e.g. copper indium gallium selenides, copper indium selenides, copper indium gallium sulfides, copper indium sulfides, copper indium gallium selenides sulfides, etc.), amorphous silicon, III-V (i.e. GaAs), II-IV (i.e. CdTe), copper zinc tin sulfide, organic photovoltaics, nanoparticle photovoltaic, dye sensitized solar cells, and combinations of the like.

Additional optional layers (not shown) may be used on the article 10 in accordance with conventional practices now shown or hereafter developed to help enhance adhesion between the various layers. Additionally, one or more barrier layers (not shown) also may be provided over the backside of flexible conductive substrate 110 to help isolate device 10 from the environment and/or to electrically isolate device 10.

In a preferred embodiment, the photovoltaic article 10 provided at the base used in the inventive method/process is what is a group IB-IIIB chalcogenide device. FIG. 2 shows one embodiment of a photovoltaic article 10 that may be used in the processes of the present invention. In the layers described below, it is contemplated that layers 22 and 24 together comprise the flexible conductive substrate, layer 20 is part of the least one photoelectrically active layer, and layer 30 is part of the top transparent conductive layer. This article 10 comprises a substrate incorporating a support 22, a backside electrical contact 24, and a chalcogenide absorber 20. The article 10 further includes an buffer region 28 comprising an n-type chalcogenide composition such as a cadmium sulfide based material. The buffer region preferably has a thickness of 15 to 200 nm. The article may also include an optional front side electrical contact window region 26. This window region protects the buffer during subsequent formation of the transparent conducting region 30. The window preferably is formed from a transparent oxide of zinc, indium, cadmium, or tin and is typically considered at least somewhat resistive. The thickness of this layer is preferably 10 to 200 nm. The article further comprises a transparent conductive region 30. Each of these components is shown in FIG. 2 as including a single layer, but any of these independently can be formed from multiple sublayers as desired. Additional layers (not shown) conventionally used in photovoltaic cells as presently known or hereafter developed may also be provided. As used occasionally herein, the top 12 of the cell is deemed to be that side which receives the incident light 16. The method of forming the cadmium sulfide based layer on the absorber can also be used in tandem cell structures where two cells are built on top of each other, each with an absorber that absorbs radiation at different wavelengths.

### Flexible Conductive Substrate 110/Electrically Conductive Film 112

It is contemplated that the photovoltaic article 10 has at least a flexible conductive substrate 110 that the article is built upon. It functions to provide a base upon which the other layers of the article are disposed upon. It also functions to provide electrical contact. It is contemplated that the substrate may be a single layer (e.g. stainless steal) or may be a multilayer composite of many materials, both electrically conductive and non-conductive layers. Examples of conductive materials include metals (e.g. Cu, Mo, Ag, Au, Al, Cr, Ni, Ti, Ta, Nb, and W), conductive polymers, combinations of these, and the like. In one preferred embodiment, the substrate is comprised of stainless steal that has a thickness that is between about 10 μm and 200 μm. It is also preferred that the substrate is flexible, with “flexible” being defined as the “flexible” item, element, or layer (in a usable thickness pursuant to the present invention) that can bend about a 0.1 meter diameter cylinder without a decrease in performance or critical damage.

In the device shown in FIG. 2, the flexible conductive substrate comprises layers 22 and 24. The support 22 may be a flexible substrate. Support 22 may be formed from a wide range of materials. These include metals, metal alloys, intermetallic compositions, plastics, paper, woven or non-woven fabrics, combinations of these, and the like. Stainless steel is preferred. Flexible substrates are preferred to enable maxium utilization of the flexibility of the thin film absorber and other layers.

The backside electrical contact 24 provides a convenient way to electrically couple article 10 to external circuitry. Contact 24 may be formed from a wide range of electrically conductive materials, including one or more of Cu, Mo, Ag, Al, Cr, Ni, Ti, Ta, Nb, W, combinations of these, and the like. Conductive compositions incorporating Mo are preferred. The backside electrical contact 24 may also help to isolate the absorber 20 from the support 22 to minimize migration of support constituents into the absorber 20. For instance, backside electrical contact 24 can help to block the migration of Fe and Ni constituents of a stainless steel support 22 into the absorber 20. The backside electrical contact 24 also can protect the support 22 such as by protecting against Se if Se is used in the formation of absorber 20.

It is contemplated the photovoltaic article has at least a photoelectrically active layer 120. This layer is generally disposed above the flexible conductive substrate 110 and below the top transparent conducting layer 130. This layer functions to take the input from the incident light 16 and convert it into electricity. It is contemplated that this layer may be a single layer of material or may be a multilayer composite of many materials, the composition of which may depend upon the type of photovoltaic article 10 (e.g. copper chalcogenide type cells, amorphous silicon, III-V (i.e. GaAs), II-IV (i.e. CdTe), copper zinc tin sulfide, organic photovoltaics, nanoparticle photovoltaics, dye sensitized solar cells, and combinations of the like.

The group IB-IIIB chaleogenide (e.g. copper chalcogenide) cells are preferred, in this case the absorber composes selenides, sulfides, tellurides, and/or combinations of these that include at least one of copper, indium, aluminum, and/or gallium. More typically at least two or even at least three of Cu, In, Ga, and Al are present. Sulfides and/or selenides are preferred. Some embodiments include sulfides or selenides of copper and indium. Additional embodiments include selenides or sulfides of copper, indium, and gallium. Aluminum may be used as an additional or alternative metal, typically replacing some or all of the gallium. Specific examples include but are not limited to copper indium selenides, copper indium gallium selenides, copper gallium selenides, copper indium sulfides, copper indium gallium sulfides, copper gallium sulfides, copper indium sulfide selenides, copper gallium sulfide selenides, copper indium aluminum sulfides, copper indium aluminum selenides, copper indium aluminum sulfide selenide, copper indium aluminum gallium sulfides, copper indium aluminum gallium selenides, copper indium aluminum gallium sulfide selenide, and copper indium gallium sulfide selenides. The absorber materials also may be doped with other materials, such as Na, Li, or the like, to enhance performance. In addition, many chalcogenide materials could incorporate at least some oxygen as an impurity in small amounts without significant deleterious effects upon electronic properties. This layer may be formed by sputtering, evaporation or any other known method. The thickness of this layer is preferably 0.5 to 3 microns.

In the copper chalcogenide cell the optional buffer and window layers may be considered part of either the active layer 120 or the transparent conducting layer 130 for purposes of understanding in what layers the channel are formed. However, preferably the buffer layer is considered part of the active layer 120 and the window layer is considered part of the transparent conducting layer 130.

### Top Transparent Conducting Layer 130

It is contemplated the photovoltaic article 10 has at least a top transparent conducting layer 130. This layer is generally disposed above the photoelectrically active layer 120 and may represent the outer most surface of the article (generally the surface that first receives the incident light 16). This layer is preferably transparent, or at least translucent, and allows the desired wavelengths of light to reach the photoelectrically active layer 120. It is contemplated that this layer may be a single layer of material or may be a multilayer composite of many materials, the composition of which may depend upon the type of photovoltaic article 10 (e.g. copper chalcogenide type cells (e.g. copper indium gallium selenides, copper indium selenides, copper indium gallium sulfides, copper indium sulfides, copper indium gallium selenides sulfides, etc.), amorphous silicon, III-V (i.e. GaAs), II-IV (i.e. CdTe), copper zinc tin sulfide, organic photovoltaics, nanoparticle photovoltaics, dye sensitized solar cells, and combinations of the like. However, preferably the transparent conducting layer 130 is a very thin metal film (such that it is at least somewhat transparent to light) or a transparent conductive oxide. A wide variety of transparent conducting oxides; very thin conductive, transparent metal films; or combinations at these may be used, but transparent conductive oxides are preferred. Examples of such TCOs include fluorine-doped tin oxide, tin oxide, indium oxide, indium tin oxide (ITO), aluminum doped zinc oxide (AZO), zinc oxide, combinations of these, and the like. TCO layers are conveniently formed via sputtering or other suitable deposition technique. The transparent conducting layer preferably has a thickness of from 18 to 1500 nm and more preferably 100 to 300 nm.

It is contemplated that a number of channels will be “formed” into the article 10 in the process to produce the two or more thin-film-based interconnected photovoltaic cells. These channels function to separate the article into individual cells, or provide pathways for conductive materials 180 and can be any number of shapes and sizes. It is contemplated that the channels may be formed via any number of processes, for example via mechanical scribe, laser ablation, etching (wet or dry), photolithography, or other methods common to the industry for selectively removing material from a substrate. The channels may be of various widths, depths, and profiles, depending on what may be desired and which channel is being formed (e.g. first, second, or third channels). Preferred cell sizes would be greater than 0.7 cm on a side, preferably greater than 10 cm and more preferably greater than 20 cm. Cells are preferably less than 2 meters and more preferably less than 15 meters on a side. A cell may have one shorter side and one longer side. Generally, the smaller the cell, it may be desirable to have a smaller channel. Preferably, one would typically wish to maximize the power density of the cell 100, or in other words minimize the gap size (channel size) to about 5% or less of the module area, thereby providing 95% or more active PV surface that can produce power. Thus, if may be preferred to have a wide range of channel widths, depending on cell 100 sizes and the desired power density. It is also contemplated that the channels may be introduced to the article in the order stated below (e.g. preferably the first channel first, second channel second, third channels, etc.) or in any other order if so desired.

### First Channel 140/Addition 141

It is contemplated that the first channel 140 be formed through the entirety of the article 10, or at least the layers 110, 120, and 130. The first channel functions to both physically and electrically isolate two portions of the article (e.g. making two cells 100) from each other. It is preferred that the first channel have a width that allows for the finished cells to flex without the channel closing up. Additionally, in one step, an addition 141 to the first channel 140 is made to go through a insulating layer 150, which is typically placed on the structure after the first channel is formed (although it could be done in a different order). In one preferred embodiment, the first channel has a width FC_{W} that can be about 1 μm to 5000 μm. It is preferred that the width is greater than about 10 μm, more preferably greater than about 25 μm and most preferably greater than about 50 μm, and preferably a width less than about 400 μm, more preferably leas than about 300 μm and most preferably less than about 200 μm. Of note, the addition 141 may have a width that is smaller, the same size as, or larger than that of the first channel.

### Second Channel 160

It is contemplated that the second channel 180 be formed through the first insulating layer 150 (and any additional layers that may exist on below or above it) and to such a depth that at least a portion of the flexible conductive substrate is exposed (e.g. at least the electrically conductive portion of it). The second channel functions as a physical path that allows the at least two thin-film-based interconnected photovoltaic cells to the electrically interconnected (e.g. see the applying an electrically conductive material step). It is contemplated that geometrically, the first and second channels be offset from one another, thus minimizing the chance that the first and second channels combine to become a through-hole. In a preferred embodiment, the offset FFS_{O} can be about 1 μm to 5000 μm. It is preferred that the offset is greater than about 10 μm, more preferably greater than about 25 μm and moat preferably greater than about 50 μm, and preferably an offset less than about 400 μm, more preferably less than about 300 μm and most preferably less than about 200 μm. In a preferred embodiment, the second channel has a depth that at least exposes a portion of the flexible conductive substrate and can go into the flexible conductive substrate, but not completely through it, and most importantly exposes the conductive material (see the applying an electrically conductive material step). Is also preferred that the second channel have a width that allows for the finished cells to flex without the channel closing up. In one preferred embodiment, the second channel has a width SC_{W} that can be about 1 μm to 500 μm. It is preferred that the width is greater than about 10 μm, more preferably greater than about 25 μm, most preferably greater than about 50 μm, and preferably a width less than about 400 μm, and more preferably less than about 300 μm, most preferably less than about 200 μm.

### Third Channel 170/Fourth Channel 172

It is contemplated that the third channel 170 be formed through the electrically conductive film 112 (and any additional layers that may exist on below or above the layers) and to the first insulating layer 150 to such a depth that at least a portion of the first insulating layer is exposed (although going partially through layer 150 is acceptable). The third channel functions to both physically and electrically isolate two portions of the electrically conductive film 112 from each other. It is contemplated that geometrically, the third channel is off-set from the first and second channels, in a preferred embodiment the offset TFS_{O} can be about 1 μm to 5000 μm. It is preferred that the width is greater than about 10 μm, more preferably greater than about 25 μm and most preferably greater than about 50 μm, and preferably a width less than about 400 μm, more preferably less than about 300 μm and most preferably less than about 200 μm. In a preferred embodiment the third channel has a width that allows for the finished cells to flex without the channel closing up. In one preferred embodiment, the third channel has a width TC_{W} that can be about 1 μm to 5000 μm. It is preferred that the width is greater than about 10 μm, more preferably greater than about 25 μm and most preferably greater than about 50 μm, and preferably a width less than about 400 μm, more preferably less than about 300 μm and most preferably less than about 200 μm.

It is contemplated that the fourth channel 172 be formed through layers 130, 120, 110, and 150 (and any additional layers that may exist on below or above the layers) and to the first insulating layer 150 to such a depth that at least a portion of the first insulating layer is exposed (although going partially through layer 150 is acceptable). The fourth channel functions to both physically and electrically isolate two portions of the finished cells 100. It is contemplated that geometrically, the fourth channel is off-set from the first and second channels, and disposed in-between them. In a preferred embodiment, the offset FS_{O} can be about 1 μm to 500 μm. It is preferred that the offset is greater than about 10 μm, more preferably greater then about 25 μm and most preferably greater then about 50 μm, and preferably a width less than about 400 μm, more preferably less than about 300 μm and most preferably less than about 200 μm. In a preferred embodiment, the fourth channel has a width that allows for the finished cells to flex without the channel closing up. In one preferred embodiment, the fourth channel has a width FC_{W} that can be about 1 μto 5000 μ. It is preferred that the width is greater then about 10 μm, more preferably greater than about 25 μm and most preferably greater then about 50 μm, and preferably a width less than about 400 μm, more preferably less than about 300 μm, and most preferably less than about 200 μm.

It is contemplated that “forming” of the various layers of the article 10 may be achieved via numerous methods, for example as discussed above in the “channels” paragraphs. In one preferred embodiment, a mechanical scribe is utilized to make a “cut”.For example, with mechanical scribing, a diamond-tipped stylus or blade may be placed in contact with the device and dragged across the surface of the device, physically tearing the underlying material in the path of the stylus.

It is contemplated that mechanical scribing, with the use of a diamond-tipped stylus or appropriate blade, may work for the softer semiconductor materials such as CdTe, copper indium gallium diselenide (CIGS), and a-Si:H. It is believed that tearing of the film is a particular problem for films such as zinc oxide (ZhO) that have low adhesion. Mechanical scribing of harder films such as molybdenium on glass invariably leads to scoring of the glass, which then contributes to increased risk of breakage in subsequent processing.

It is also believed that most of the problems encountered with mechanical scribing do not occur with laser scribing. In a recently completed a survey of laser systems, as applied to the thin-film materials used in the CdTe-based and CIS-based PV modules (See:http//www.laserfocusworld.com/articles/print/volume-36/issue-1/features/photovoltaics-laser-scribing-creates-monolithic-thin-film-arrays.html, which is incorporated by reference) has found that good scribes can be obtained with a wide variety of pulsed lasers, such as Nd:YAG (lamp-pumped, diode-pumped, Q-switched, and modelooked), copper-vapor, and xenon chloride and krypton fluoride excimer lasers. It is believed that it may be important when choosing a laser, to pay attention to the specific material properties (absorption coefficient, melting temperature, thermal diffusivity, and so on) of the films used in the solar cells.

### Insulating Segment/Layer 150/152; Carrier Structure 230

Its is contemplated that there may be one or more insulating layers 150/152 disposed in areas of the finished cells 100. Generally, one function of an insulating layer may be to provide a protective barrier (e.g. environmentally and/or electrically) for the portions covered by this layer, keeping out dirt, moisture, separating other layers (e.g. electrically insulating), and the like. It can also function to hold the cells 100 together, akin to “taping” two adjoining cells together. A “layer” may be a solid layer that spans the entire cell 100, or could be localized to only certain areas. In one example, layer 152 can span across substantially the entire bottom of the cell 100 or just locally about the area of a channel.

In a preferred embodiment, the finished cell includes two insulating layers 150/152. A first insulating layer (or film) 152 that is disposed between conductive substrates or films and a second layer (or film) 152 that is disposed at the bottom of the cells 100. These layers 150, 152 preferably are composed of the same materials and have the same geometric and physical properties, but it is contemplated that they do not necessarily have to be. It may he desirable that the second layer 152 may be thicker or may be in separate segments, functioning to “tape” two adjoining cells 100 together.

In a preferred embodiment, the insulating layers 150/152 can have a thickness IL_{γ} of about 100 nm to 1000 μm. It is preferred that the thickness is greater than about 1 μm, more preferably greater than about 25 μm and most preferably greater than about 75 μm, and preferably a thickness leas than about 500 μm, more preferably less than about 200 μm and most preferably less than about 100 μm.

The Insulating layer may comprise any number of materials that are suitable for providing protection as described above. Preferred materials include: silicon oxide, silicon nitride, silicon carbide, titanium oxide, aluminum oxide, aluminum nitride, boron oxide, boron nitride, boron carbide, diamond like carbon, epoxy, silicone, polyester, polyfluorene, polyolefin, polyimide, polyamide, polyethylene, polyethylene terephalate, fluoropolymers, paralyene, urethane, ethylene vinyl acetate, or combinations of the like.

If is also contemplated that a layer similar to the insulating layer (at least possibly a similar material) be provided on the top of the article or the cell. This layer may function as a carrier structure 230 that may aid in moving or packaging the article and/or the cell. If a carrier structure is provided, it should be readily removable so that the cuts (e.g. formation of the channels) can be made or the finished cells can be installed in a larger PV device.

The carrier structure may comprise any number of materials that are suitable for providing functionality as described above. Preferred materials include materials listed for the insulated layer.

Electrically Insulating Material (top of cell)

It is contemplated that optionally some electrically insulating material (not shown) may be disposed within the fourth channel. This material may function to provide a protective barrier (e.g. environmentally and/or electrically) for the portions covered by the material, keeping out dirt, moisture, and the like. The electrically insulating material may comprise any number or material that are suitable tor providing protection as described above. Preferred materials include: silicon oxide, silicon nitride, silicon carbide, titanium oxide, aluminum oxide, aluminum nitride, boron oxide, baron nitride, boron carbide, diamond like carbon, epoxy, silicone, polyester, polyfluorene, polyolefin, polymide, polyamide, polyethylene, polyethylene terephalate, fluoropolymers, paralyene, urethane, ethylene vinyl acetate, or combinations of the like.

It is contemplated that an electrically conductive material 180 is used in the process to interconnect the photovoltaic cells 100. In the present invention, the material may be used in conjunction with the second channel and should be in contact with an electrically conductive portion of the flexible conductive substrate 110 and the top of the top transparent conducting layer 130. Also, it may be used to connect the two conductive layers 110/112 via channel 160. The electrically conductive material may comprise any number of materials that are suitable for providing electrical conductivity and include: the electrically conductive material may desirably at least include a conductive metal such as nickel, copper, silver, aluminum, tin, and the like and/or combinations thereof. In one preferred embodiment, the electrically conductive material comprises silver. It is also contemplated that electrically conductive adhesives (ECA) may be any such as are known in the industry. Such ECA's are frequently compositions comprising a thermosetting polymer matrix with electrically conductive polymers. Such thermosetting polymers include but are not limited to materials having comprising epoxy, cyanate ester, maleimide, phenolic, anhydride, vinyl, allyl or amino functionalities or combinations thereof. The conductive filler particles may be for example silver, gold, copper, nickel, aluminum, carbon nanotubes, graphite, tin, tin alloys, bismuth or combinations thereof. Epoxy based ECAs with silver particles are preferred. The electrically conductive material region can be formed by one of several known methods including but not limited to screen printing, ink jet printing, gravure printing, electroplating, sputtering, evaporating and the like.

The interconnected cells formed by this method can be encapsulated or packaged within protective materials (encapsulants, adhesives, glass, plastic films or sheets, etc.) and electrically interconnected of made electrically connectable to power converters or other electrical devices to form photovoltaic modules that can be installed in the field or on structures to produce and transmit power.

Unless stated otherwise, dimensions and geometries of the various structures depleted herein are not intended to be restrictive of the invention, and other dimensions or geometries are possible. Plural structural components can be provided by a single integrated structure. Alternatively, a single integrated structure might be divided into separate plural components. In addition, while a feature of the present invention may have been described in the context of only one of the illustrated embodiments, each feature may be combined with one or more other features of other embodiments, for any given application, it will also be appreciated from the above that the fabrication of the unique structures herein and the operation thereof also constitute methods in accordance with the present invention.

The use of the terms “comprising” or “including” describing combinations of elements, ingredients, components or steps herein also contemplates embodiments that consist essentially of the elements, ingredients, components or steps.

Plural elements, ingredients, components or steps can be provided by a single integrated, element, ingredient, component or step. Alternatively, a single integrated element, ingredient, component or step might be divided into separate plural elements, ingredients, components or steps, the disclosure of “a” or “one” to describe an element, ingredient, component or step is not intended to foreclose additional elements, ingredients, components or slaps. All references herein to elements or metals belonging to a certain Group rater to the Periodic Table of the Elements published and copyrighted by CRC Press, Inc., 1989, Any reference to the Group or Groups shall be to the Group or Groups as reflected In this Periodic Table of the Elements using the IUPAC system for numbering groups.

1. A method of producing two or more thin-film-based interconnected photovoltaic ceils comprising the steps of:
a) providing a photovoltaic article comprising: a flexible conductive substrate, at least one photoelectrical active layer, a top transparent conducting layer, end a carrier structure disposed above the top transparent layer;
b) forming one or more first channels through the layers of the photovoltaic article;
c) applying a first insulating layer to the conductive substrate and spanning the one or more first channel;
d) removing the carrier structure;
e) forming an addition to the one or more first channels through the first insulating layer;
f) forming one or more second channels off set from the one or more first channels through the first insulating layer to expose a conductive surface of the flexible conductive substrate;
g) applying a first electrically conductive material to the conductive surface of the flexible conductive substrate via the one or more second channels;
h) applying an electrically conductive film to the first insulating layer, wherein the film Is In electrical communication with the flexible conductive substrate via the first electrically conductive material;
i) applying a second electrically conductive material above the top transparent conducting layer and through the one or more first channels, electrically connecting the layers of the photovoltaic article from step b to the electrically conductive film;
j) forming one or more third channels through the electrically conductive film;
k) applying a second insulating layer below the electrically conductive film;
l) forming one or more fourth channels through the layers of the photovoltaic article, thus producing two or more interconnected photovoltaic cells.

2. The method according to claim 1, further comprising the step of at least partially filling the one or more fourth channels with an electrically insulating material.

3. The method according to claim 2, wherein the electrically insulating material comprises silicon oxide, silicon nitride, titanium oxide, aluminum oxide, non-conductive epoxy, silicone, polyester, polyfluorene, polyolefin, polyimide, polyamide, polyethylene or combinations of the like,

4. The method according to claim 1, wherein the insulating layer comprises polyester, polyolefin, polyimide or polyamide.

5. The method according to claim 1, wherein the forming step is carried out by scribing, cutting, ablating, or combinations of the like.

6. The method according to claim 1, wherein the photovoltaic article cell is in roll form.

7. The method according to claim 1, wherein the second insulating layer functions in a bottom carrier film.

8. The method according to claim 1, wherein the width of the channels of the forming step are from 1 to 5000 microns.

9. A photovoltaic article formed by the method claim 1.

10. The photovoltaic article according to claim 9, wherein the one or more fourth channels are partially filled with an electrically insulating material.

11. The photovoltaic article according to claim 10, wherein the electrically insulating material comprises silicon oxide, silicon nitride, titanium oxide, aluminum oxide, non-conductive epoxy, silicone, polyester, polyfluorene, polyolefin, polyimide, polyamide. polyethylene or combinations of the like.

12. The photovoltaic article according to claim 9, wherein the insulating layer comprises polyester, polyolefin, polyimide or polyamide.

13. The photovoltaic article according to claim 9, wherein the photovoltaic article cell is in roll form.

14. The photovoltaic article according to claim 9, wherein the second insulating layer functions as a bottom carrier film.

15. The photovoltaic article according to claim 9, wherein the width of the channels are from 1 to 5000 microns.
